(19) United States
(12) Patent Application Publication
(10) Pub. No.: US 2015/0093231 A1
(43) Pub. Date: Apr. 2, 2015

(54) ADVANCED CRUCIBLE SUPPORT AND THERMAL DISTRIBUTION MANAGEMENT

(71) Applicant: GT Crystal Systems, LLC, Salem, MA (US)

(72) Inventor: David F. Broyer, Kingston, NH (US)

(21) Appl. No.: 14/488,501

(22) Filed: Sep. 17, 2014

Related U.S. Application Data
(60) Provisional application No. 61/884,503, filed on Sep. 30, 2013.

(51) Int. Cl. B25J 15/00; B25J 11/00; F16M 13/00; C30B 11/00; C30B 15/10

(52) U.S. Cl. CPC B25J 15/0095; C30B 11/007; C30B 15/10; F16M 13/00; B25J 11/00
USPC 414/800; 248/346.5; 248/558

(57) ABSTRACT

According to the disclosed embodiments, an advanced crucible support system is described that allows for greater heat flow to and from the bottom of a crucible, while also preventing excessive heat from reaching a heat exchanger. In particular, a “crown” support base is described that provides heat flow throughout the system, yet with various features to limit the amount of heat reaching the heat exchanger. Also, according to one or more additional embodiments, the functionality of the crucible support is adapted to be leveraged by a crucible manipulating device. For example, the support plate may have features designed within it for enabling lifting devices to interface with it, such as a plurality of slots for insertion of a “lifting arm”, such that the entire support plate assembly, as well as the crucible itself while on the support assembly, may be lifted and transported as a single unit.

### CROSS-REFERENCE TO RELATED APPLICATION

The present application claims the benefit of U.S. Patent Application No. 61/884,503 filed Sep. 30, 2013, which is incorporated herein by reference.

### TECHNICAL FIELD

The present disclosure relates generally to crystalline material growth systems, and, more particularly, to an advanced crucible support and thermal distribution management.

### BACKGROUND

Crystal growth apparatuses or furnaces, such as directional solidification systems (DSS), Czochralski (CZ) method furnaces, and heat exchanger method (HEM) furnaces, involve the melting and controlled resolidification of a feedstock material, such as silicon or sapphire, in a crucible to produce an ingot or boule. Production of a solidified ingot from molten feedstock occurs in several identifiable steps over many hours. For example, to produce a silicon ingot by the DSS method, solid silicon feedstock is provided in a crucible, often contained in a graphite crucible box, and placed into the hot zone of a DSS furnace. Alternatively, to produce an ingot, such as a sapphire ingot, by the HEM method, solid feedstock, such as alumina, is provided in a crucible containing a monocrystalline seed (which comprises the same material as the feedstock but with a single crystal orientation throughout) placed into the hot zone of a solidification furnace. A heat exchanger, such as a helium-cooled heat exchanger, is positioned in thermal communication with the crucible bottom and with the monocrystalline seed.

The feedstock in either method is then heated to form a liquid feedstock melt (without substantially melting the monocrystalline seed in the HEM method), and the furnace temperature, which is well above the seed melting temperature (e.g., 1412° C. for silicon), is maintained for several hours to ensure proper melting. Once melted, heat is then removed from the melted feedstock, often by applying a temperature gradient in the hot zone, in order to directionally solidify the melt (e.g., from the unmelted seed) to form an ingot. By controlling how the melt solidifies, an ingot having greater purity than the starting feedstock material can be achieved, and in the case of the HEM method a crystalline material having a crystal orientation corresponding to that of the monocrystalline seed can be achieved, which can each then be used in a variety of high end applications, such as in the semiconductor and photovoltaic industries.

For stability, crucibles are placed into a furnace atop a support structure that generally matches the shape of the crucible's base. Typically, these supports are a solid material, and may generally take the shape of a solid ring, in which the crucible sits. The current crucible support design, however, limits the “view factor” for radiated heat generated from a furnace's heating element from reaching the bottom of the crucible. Because of this fact, the temperature gradient at the base of the crucible is not ideal.

Additionally, the current method of using the crucible itself as a means for establishing a physical interface for a given crucible manipulating device is presenting challenges and safety concerns as the physical size and mass of crucible and charge size increases. In the crystal growth process a ring is used for supporting of the crucible within the hot zone. The ring is currently manually loaded into the furnace as its own discrete loading step, and then several steps follow before a crucible is fully charged and considered ready for the crystal growth process, thus causing issues for any automation requirements for the crucible loading process.

### SUMMARY

According to the disclosed embodiments, an advanced crucible support system is described that allows for greater heat flow to and from the bottom of a crucible, while also preventing excessive heat from reaching a heat exchanger. In particular, a “crown” support base is described that provides heat flow throughout the system, yet with various features to limit the amount of heat reaching the heat exchanger.

According to one or more additional embodiments, the functionality of the crucible support is adapted to be leveraged by a crucible manipulating device. For example, the support plate may have features designed within it for enabling lifting devices to interface with it, such as a plurality of slots for insertion of a “lifting arm”, such that the entire support plate assembly, as well as the crucible itself while on the support assembly, may be lifted and transported as a single unit.

### BRIEF DESCRIPTION OF THE DRAWINGS

The foregoing and other objects, features, aspects and advantages of the embodiments disclosed herein will become more apparent from the following detailed description when taken in conjunction with the following accompanying drawings, of which:

FIG. 1 illustrates an example furnace and crucible configuration;

FIG. 2 illustrates an example boule production process;

FIG. 3 illustrates an example crucible crown support;

FIG. 4 illustrates an example crucible crown support system;

FIG. 5 illustrates an example of shims for the crucible support;

FIG. 6 illustrates an example crucible support configured for lifting support;

FIG. 7 illustrates an example crucible manipulator;

FIG. 8 illustrates an example manipulator layout;

FIG. 9 illustrates another example manipulator layout; and

FIG. 10 illustrates an exemplary procedure for use with an advanced crucible support and thermal distribution management system.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION OF THE EMBODIMENTS

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

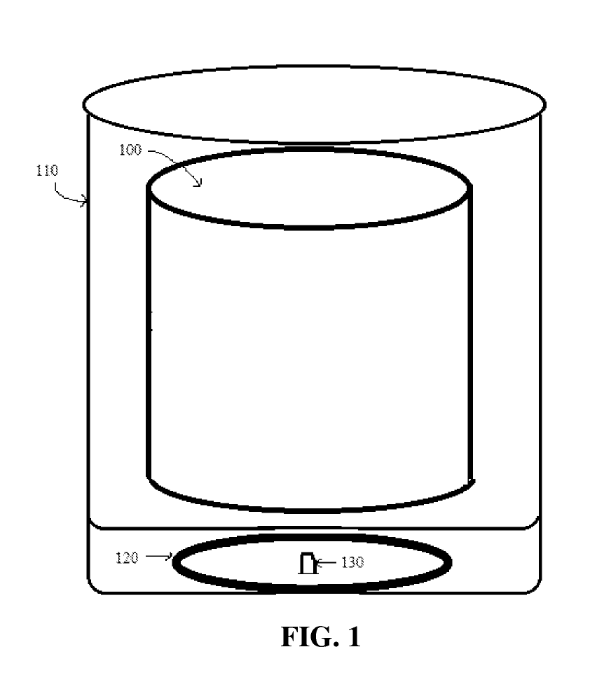

FIG. 1 illustrates a conventional crystalline material growth system. As shown in FIG. 1, a conventional crystalline material growth system includes a crucible 100, a furnace 110, a crucible support (e.g., ring) 120, and a heat exchanger shaft 130.

The crucible 100 can conventionally be any container known in the art for holding, melting, and resolidifying a feedstock material. For example, when producing silicon or sapphire crystal, quartz or graphite crucibles are typical, respectively. Additionally or alternatively, the crucible 100 may be made of, for example, molybdenum, silicon carbide, silicon nitride, composites of silicon carbon or silicon nitride with silica, pyrolytic boron nitride, alumina, or zirconia and, optionally, may be coated, such as with silicon nitride, to prevent cracking of the ingot after solidification. The crucible 100 may also have a variety of different shapes having at least one side and a bottom, including, for example, cylindrical, cubic or cuboid (having a square cross-section), or tapered.

The crucible 100 may be disposed in an interior portion of a crystallization furnace 110 including a furnace chamber having a bottom wall and side walls that define the interior portion. The crystallization furnace may be any device suitable for heating and melting a feedstock material at high temperatures, e.g., greater than 1000° C., and subsequently for allowing resolidification of the melted feedstock material. Suitable furnaces include, for example, crystal growth furnaces and DSS furnaces. Typically, the furnace may be provided in two parts, e.g., a furnace top and a furnace bottom, which can be separated in order to access the interior portion of the furnace, for example, to load the crucible 100 therein.

The heat exchanger 130 may include an elongated shaft that extends in a vertical direction, e.g., an up-and-down direction as shown in FIG. 1, and traverses the bottom wall of the furnace chamber. A first end portion of the heat exchanger shaft 130 may be coupled to the crucible 100, and particularly, a base of the crucible. The heat exchanger 130 may maintain a particular temperature of a melted feedstock by allowing cooling fluid to pass through the heat exchanger shaft.

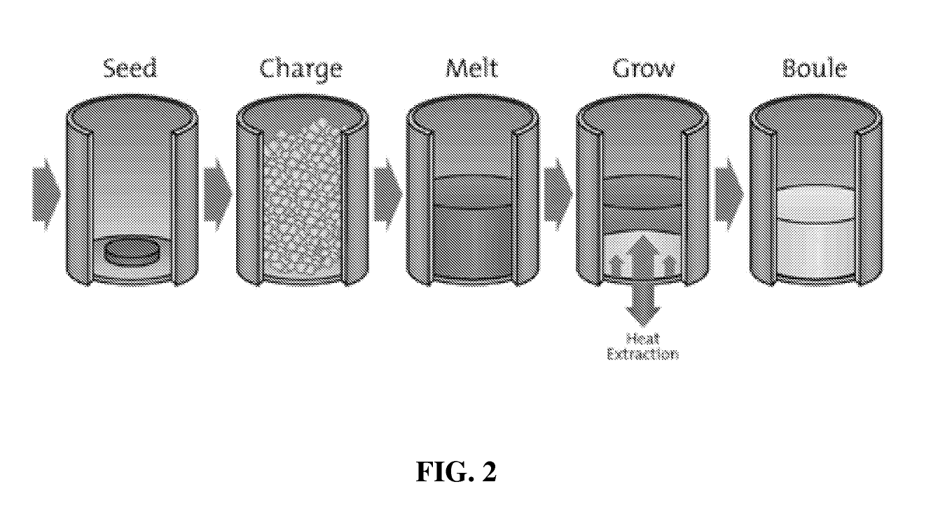

With reference generally to FIG. 2, in a typical HEM implementation, a “seed” may be placed into the crucible, and then feedstock or “charge” material, e.g., silicon or aluminum oxide, may be placed into the crucible 100 and then melted by heating the crucible walls. During the melting, the heat exchanger maintains the seed crystal at a temperature slightly below its melting point, e.g., using cooling fluid passing through the heat exchanger shaft, to keep the seed is in solid form. After the feedstock material is melted, it may be cooled to allow for resolidification through heat extraction, and crystallization (“growth”) initiates and the resolidified material expands in three dimensions. When crystallization is complete, the furnace temperature is decreased and the crystal ingot (boule) slowly anneals. The crystallization process in its entirety may take approximately 72 hours.

As discussed above, crucibles are placed into a furnace atop a support structure 120 that generally matches the shape of the crucible's base. Typically, these supports are a solid material, and may generally take the shape of a solid ring. The current crucible support design, however, limits the “view factor” for radiated heat generated from a furnace's heating element from reaching the bottom of the crucible. Because of this fact, the temperature gradient at the base of the crucible is not ideal.

The present disclosure thus provides an advanced crucible support system that allows for greater heat flow to and from the bottom of the crucible, while also preventing too much heat from reaching the heat exchanger. In particular, by introducing “vents” into the support system (e.g., the “ring” 120 above), heat may more easily reach the base of the crucible during the heating process, and may also more easily leave the base during the cooling process. In addition, various features may also prevent the additional heat flow from impinging on the operation of the heat exchanger, i.e., minimizing heat transfer to the heat exchanger, allowing it to maintain its proper cooling capacity. By allowing the redirection of heat to radiate evenly in this manner, a steeper heat gradient is present at the bottom of the crucible around the heat exchanger, beneficially producing greater melting force to the base for feedstock, yet allowing the seed to maintain in its solid form nearest the heat exchanger.

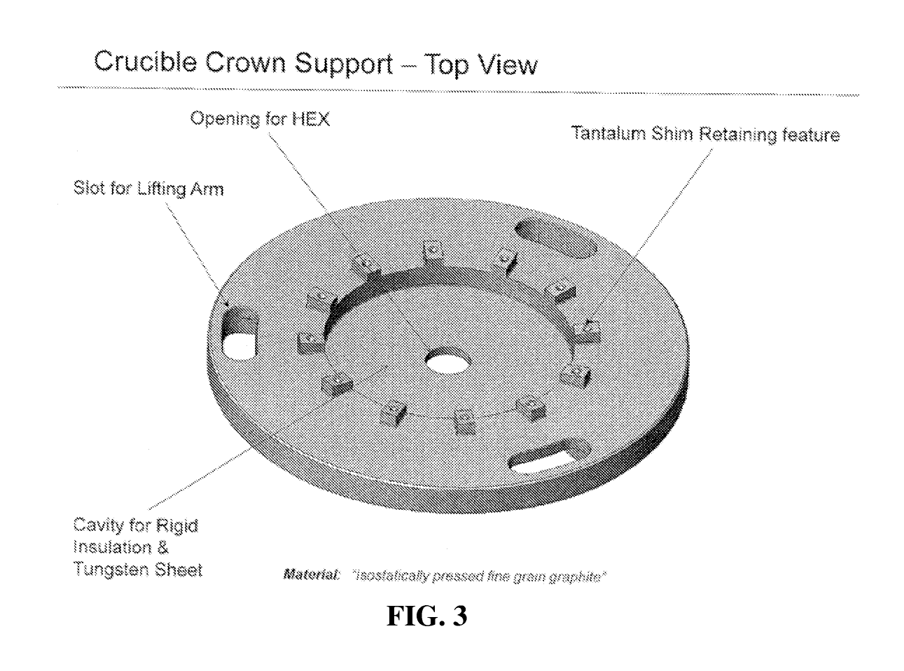

In particular, according to one or more illustrative embodiments herein, an advanced crucible support “crown” now allows for a better view factor to the bottom of the crucible. For example, with reference to FIG. 3, an example crucible crown support is shown, where raised “crown” features (e.g., with an example tantalum shim) are spaced generally evenly around a support base (e.g., an isostatically pressured fine-grain graphite material). The raised crown features allow for ventilation to and from the bottom of the crucible.

Due to the increased flow, this example crucible support crown now also exposes the heat exchanger (“HEX”) to this same radiated heating, which is a negative impact to the process. In order to mitigate heating of heat exchangers top outside diameter, insulating features may be placed within a recessed cavity surrounding the heat exchanger. For example, one implementation may use a layer of insulation inserted into the center cavity of the crucible support crown. The insulation minimizes heat conducted to heat exchanger. In addition, a layer/sheet of a material having low emissivity (e.g., tungsten) may also be inserted into the center cavity, where the low emissivity helps to reflect the radiation back to the crucible bottom. In this arrangement, the heat flow is more isothermal, thus not “bleeding” heat out of the bottom of the system (i.e., reaching the support plate), and redirecting it toward the crucible.

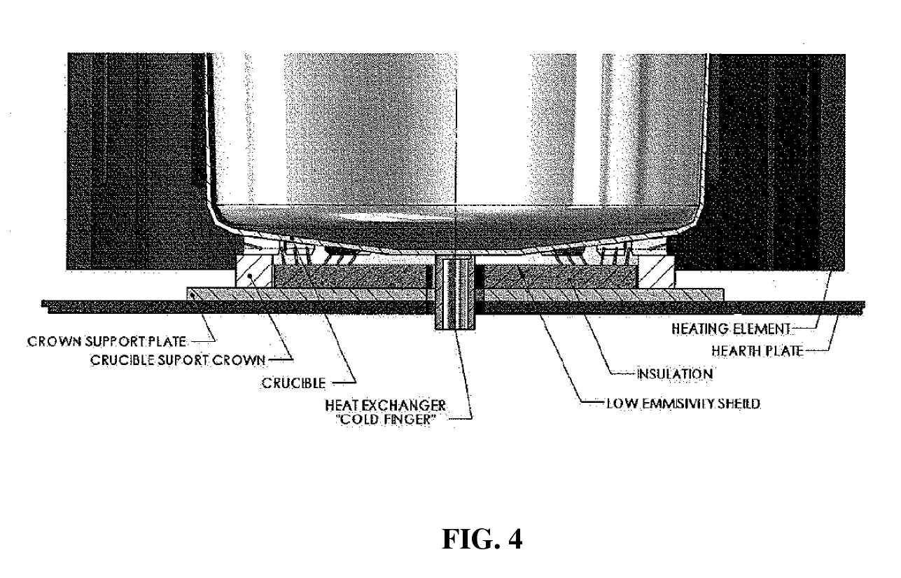

FIG. 4 illustrates an example side view of the example crucible support system of FIG. 3, showing the crucible resting on the support, and the layers of insulation and low emissivity medium (e.g., tungsten sheet). In particular, the crown support plate supports the plurality of “crown” features, surrounding a recessed cavity in which insulation and an optional low emissivity shield may be placed to prevent heat from reaching the heat exchanger (“cold finger”).

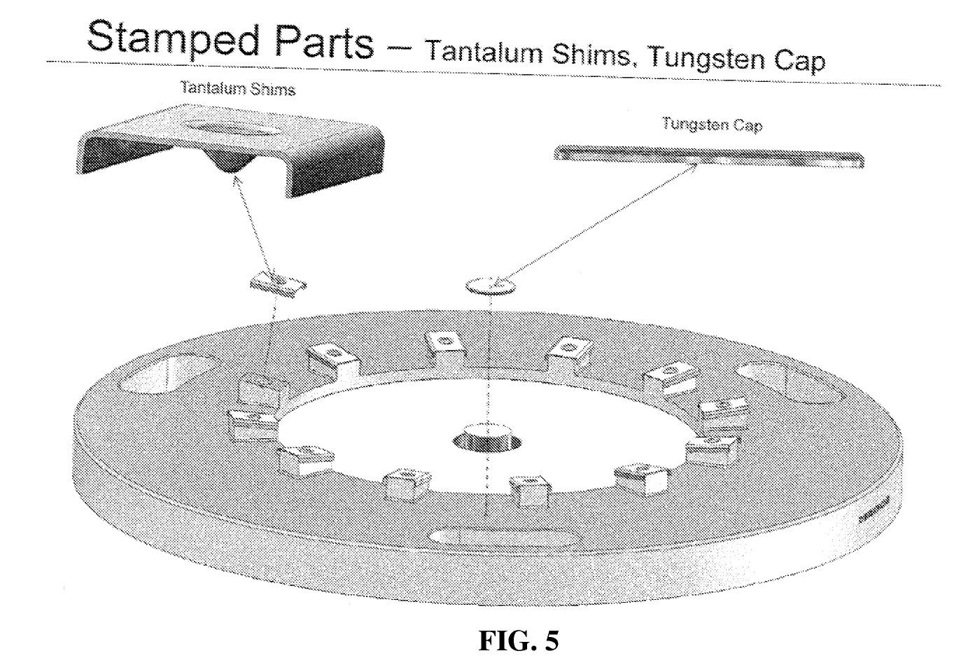

Note that as shown in FIG. 5, the crown features may have removable shims for durability, such as tantalum shims (e.g., with a retaining feature, such as a detent/protrusion arrangement), which may be replaced over time as necessary. Also, a tungsten cap may be placed onto the heat exchanger to allow for greater thermal contact to the base of the crucible.

As also mentioned above, the current method of using the crucible itself as a means for establishing a physical interface for a given crucible manipulating device is presenting challenges and safety concerns as the physical size and mass of crucible and charge size increases, and also causes issues for automation requirements due to a lengthy manual process of loading the support ring, and then the crucible, and so on.

According to one or more specific embodiments herein, the functionality of the crucible support is adapted to be leveraged by a crucible manipulating device for charging of the crucible, loading and unloading from furnace, and potentially for subsequent post crucible/boule processing steps. In particular, with reference again to FIG. 3, the support plate may have features designed within it for enabling lifting devices to interface with it, such as a plurality of slots for insertion of a “lifting arm”, such that the entire support plate assembly, as well as the crucible itself while on the support assembly, may be lifted and transported as a single unit.

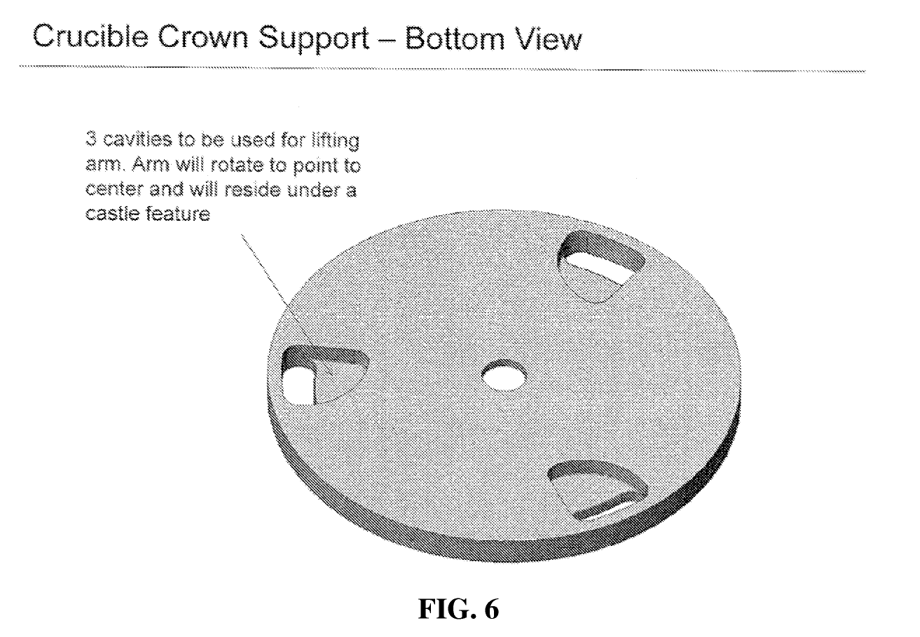

For instance, with reference now to FIG. 6, the bottom view of the support plate reveals cavities on the reverse side of the slots, such that an arm may be inserted through the slots, and rotated (e.g., toward the center) to engage the support plate. Illustratively, for strength, the cavities reside under a castle feature, though this is not a necessary implementation in the event the support plate is considered to be strong enough to support the weight of a loaded crucible between the castle features.

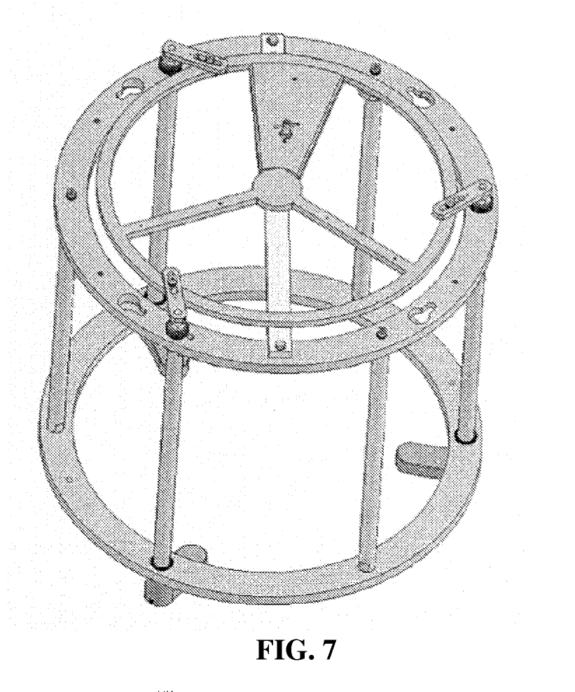

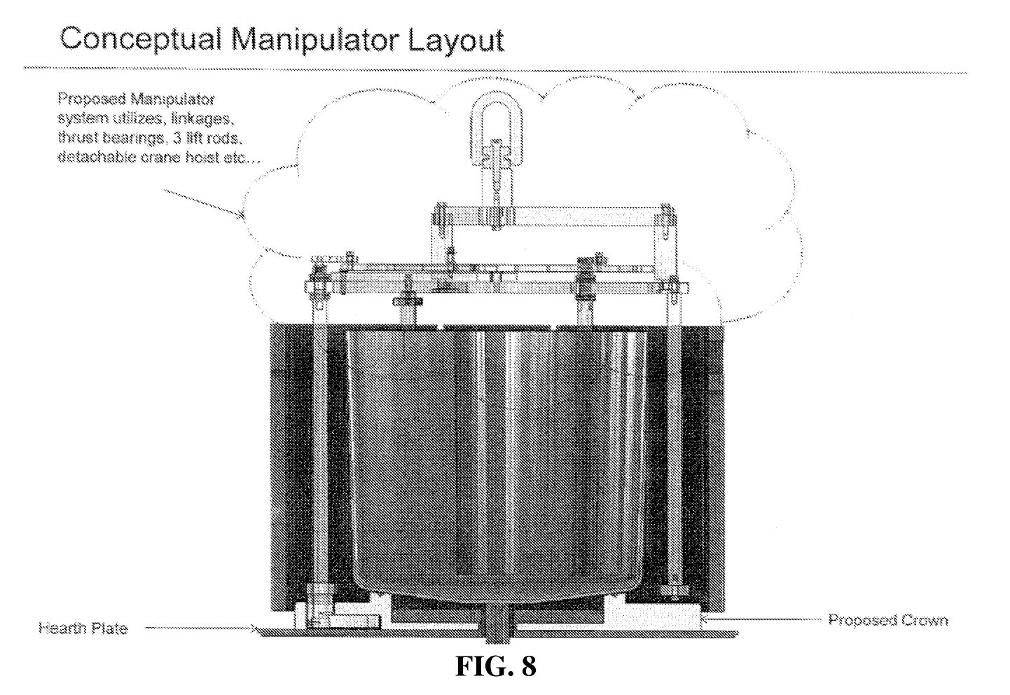

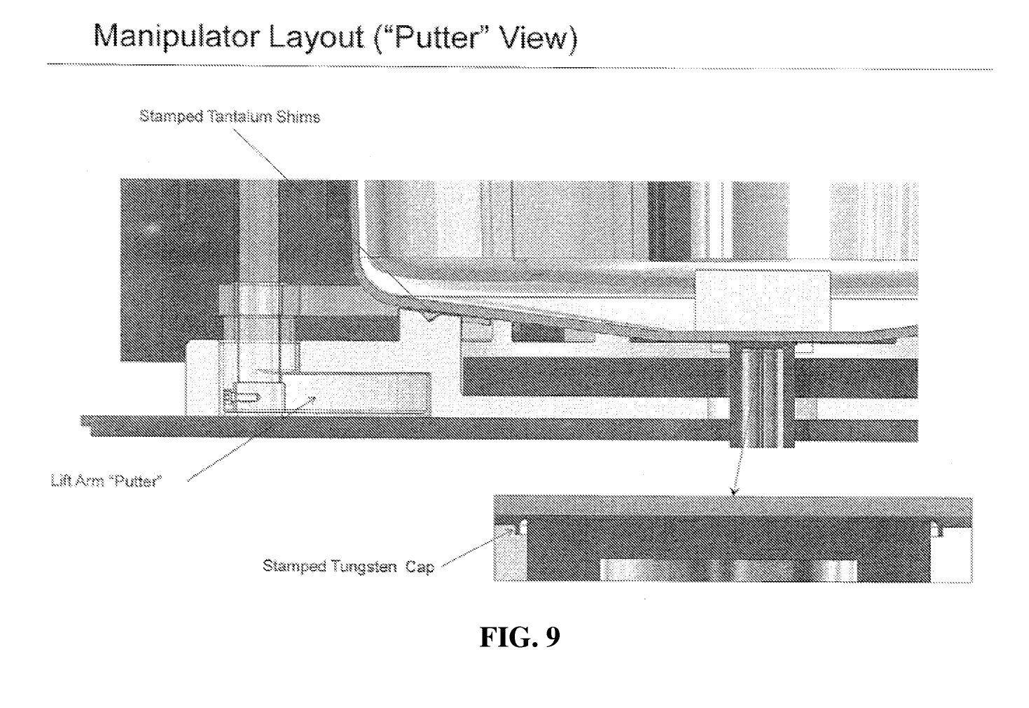

A better understanding of the crucible transportation techniques described herein may be obtained with reference to FIGS. 7-9, generally. In particular, FIG. 7 illustrates an example lifting arm mechanism (“manipulator”), which is designed to slide over a crucible, and engage the lifting arms through the slots of the support plate, as shown in greater detail in FIG. 8 and FIG. 9. (Note that the term “putter” refers to the general shape of the illustrative lifting arm representing a golfer's putter.) As shown particularly in FIG. 8, the manipulator design may implement linkages, thrust bearings, lift rods, a detachable crane hoist, etc. The top components of the lifting mechanism may comprise a configuration suitable for controlling the rotation of the lifting arms, to engage the “putter end” within the corresponding cavities of the support plate. Once engaged, the crucible and support plate may be manipulated, transported (filled or otherwise), placed into a furnace, removed from a furnace, and so on. In this manner, not only is the crucible easier to manipulate in general, but the entire arrangement lends itself well to automated facilities.

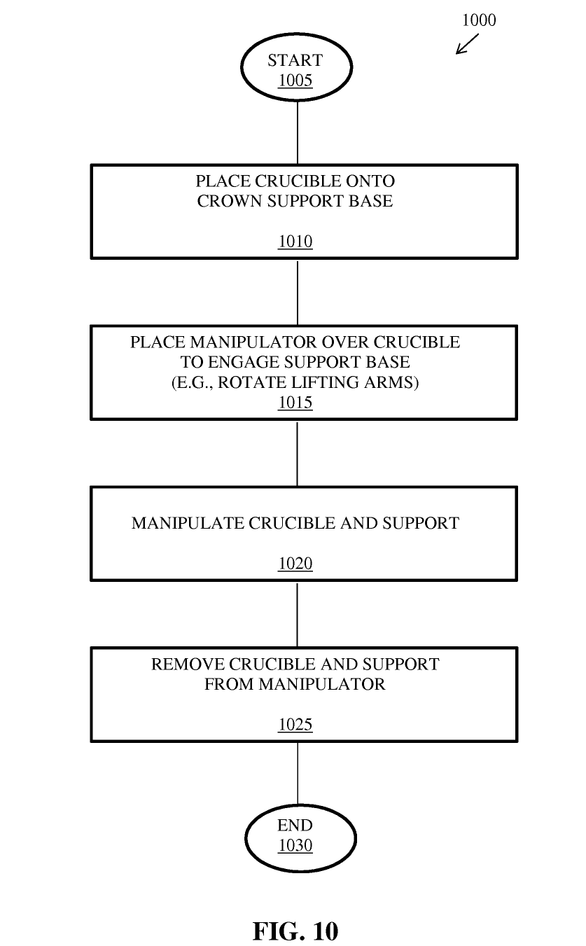

FIG. 10 illustrates an example simplified procedure for use with an advanced crucible support and thermal distribution management system. As shown in FIG. 10, the procedure 1000 may start at step 1005, continue to step 1010, where, as described in greater detail above, a crucible may be placed onto a crown support. A manipulator (lifting mechanism) may then be placed over the crucible to engage the support base in step 1015 (e.g., rotating the lifting arms), and then in step 1020 the crucible and support may be manipulated (moved, transported, etc.) to a desired location. Once complete, in step 1025 the crucible and support may be removed from the manipulator (e.g., reverse rotating the lifting arms). The procedure 1000 ends in step 1030.

Notably, procedure 1000 makes no specific reference to what actions are performed to the crucible at which times, such as filling the crucible, emptying the crucible, heating/cooling the crucible, etc., as each of these activities may occur at any time during the manipulation process. It should be understood that the steps shown in FIG. 10 are merely examples for illustration, and certain steps may be included or excluded as desired. Further, while a particular order of the steps is shown, this ordering is merely illustrative, and any suitable arrangement of the steps may be utilized without departing from the scope of the embodiments herein.

The components, arrangements, and techniques described herein, therefore, provide for an advanced crucible support and thermal distribution management. In particular, the embodiments described herein optimize support of crucibles, such as those used to grow sapphire boules, while optimizing thermal management to the crucible base, crystal seed, and a heat exchanger cap. In addition, the techniques herein change from using the crucible itself as the physical attachment interface for loading and unloading, to now using the crucible support as the mechanical interface, allowing for ease of operation and greater access for automated manufacturing processes.

While there have been shown and described illustrative embodiments that provide for an automated heat exchanger alignment means, it is to be understood that various other adaptations and modifications may be made within the spirit and scope of the embodiments herein, with the attainment of some or all of their advantages. Therefore, it is the object of the appended claims to cover all such variations and modifications as come within the true spirit and scope of the embodiments herein.

What is claimed is:

1. An apparatus, comprising:
a support base plate; and
a plurality of spaced crown features disposed on the support base plate, the crown features configured to receive and vertically support a crucible, the plurality of crown features spaced to support the crucible and to allow heat flow between the plurality of crown features.

2. The apparatus as in claim 1, further comprising:
an aperture in the support based plate configured to allow passage of a heat exchanger.

3. The apparatus as in claim 2, further comprising:
a recessed cavity formed by the support base plate, the recessed cavity contained within an interior space defined by the spaced crown features and surrounding the heat exchanger aperture; and
an insulation placed within the recessed cavity and configured to surround the heat exchanger.

4. The apparatus as in claim 3, further comprising:
a low emissivity sheet covering the insulation on a side of the insulation facing a supported crucible.

5. The apparatus as in claim 1, further comprising:
a replaceable shim on each of the plurality of crown features.

6. The apparatus as in claim 1, wherein the support base plate defines a plurality of slotted apertures, the plurality of slotted apertures each configured to allow passage of a respective lifting arm, which when rotated while through the slotted apertures, results in engagement of the support base plate by the respective lifting arm.

7. The apparatus as in claim 6, wherein the plurality of slotted apertures further define corresponding cavities for engagement of the support base plate by the respective lifting arm without the lifting arm protruding beyond a bottom plane of the support base plate.

8. A system, comprising:
a support base plate, wherein the support base plate defines a plurality of slotted apertures, the plurality of slotted apertures each configured to allow passage of a respective lifting arm, which when rotated while through the slotted apertures, results in engagement of the support base plate by the respective lifting arm; and
a manipulator having a plurality of lifting arms configured to mate with the plurality of slotted apertures and to rotate to engage the support base plate.

9. The system as in claim 7, wherein the plurality of slotted apertures further define corresponding cavities for engagement of the support base plate by the respective lifting arm without the lifting arm protruding beyond a bottom plane of the support base plate.

10. A method, comprising:
placing a crucible onto a support base;
placing a manipulator over the crucible;
engaging the support base by the manipulator; and
manipulating the crucible and support base simultaneously by the manipulator.

11. The method as in claim 10, further comprising:
removing the crucible and support base from the manipulator by disengaging the manipulator from the support base.

12. The method as in claim 10, wherein base support is a crown support.

13. The method as in claim 10, wherein engaging comprises:
placing lifting arms of the manipulator through apertures in the crucible support; and
rotating the lifting arms to engage a portion of the lifting arm with the crucible support.
